(19) United States
(12) Patent Application Publication
(10) Pub. No.: US 2025/0193515 A1
(43) Pub. Date: Jun. 12, 2025

(54) ELECTRONIC DEVICE FOR ADJUSTING, ON BASIS OF FREQUENCY, STRENGTH OF DATA SIGNAL TO BE TRANSMITTED THROUGH CONDUCTIVE PATTERN, AND METHOD PERFORMED BY ELECTRONIC DEVICE

(71) Applicant: SAMSUNG ELECTRONICS CO., LTD., Suwon-si (KR)

(72) Inventors: Kyumin CHAE, Suwon-si (KR); Youngjin KANG, Suwon-si (KR); Byoungil SON, Suwon-si (KR); Sungchan AN, Suwon-si (KR); Dongjun LEE, Suwon-si (KR); Wonhyung HEO, Suwon-si (KR)

(73) Assignee: SAMSUNG ELECTRONICS CO., LTD., Suwon-si (KR)

(21) Appl. No.: 19/060,317

(22) Filed: Feb. 21, 2025

Related U.S. Application Data
(63) Continuation of application No. PCT/KR2023/008876, filed on Jun. 26, 2023.

(30) Foreign Application Priority Data
Aug. 22, 2022 (KR) 10-2022-0105113
Sep. 16, 2022 (KR) 10-2022-0117035

(51) Int. Cl. H04N 23/661; H01Q 1/38

(52) U.S. Cl. CPC H04N 23/661; H01Q 1/38

(57) ABSTRACT

An electronic device includes: a camera; a first conductive pattern separated from the camera by a first distance; a second conductive pattern separated from the camera by a second distance, the second distance; and a communication processor to transmit a data signal to an external electronic device and to receive a control signal from the external electronic device. The communication processor transmits a first data signal to the external electronic device by controlling the first conductive pattern and the second conductive pattern in a first time period indicated by the control signal transmitted from the external electronic device; transmits a second data signal to the external electronic device by controlling the second conductive pattern in a second time period; and adjust a strength of the first data signal to be lower than a preset strength.

### CROSS-REFERENCE TO RELATED APPLICATIONS

This application is a by-pass continuation application of International Application No. PCT/KR2023/008876, filed on Jun. 26, 2023, which is based on and claims priority to Korean Patent Application Nos. 10-2022-0105113, filed on Aug. 22, 2022, and 10-2022-0117035, filed on Sep. 16, 2022, in the Korean Intellectual Property Office, the disclosures of which are incorporated by reference herein their entireties.

### BACKGROUND

### 1. Field

One or more embodiments describe an electronic device for adjusting, on the basis of a frequency, strength of a data signal to be transmitted through a conductive pattern, and a method performed by the electronic device.

### 2. Description of Related Art

An electronic device may transmit a signal through a conductive pattern or receive the signal through the conductive pattern. The electronic device may include a conductive area filled with a conductive material in a portion of an outer periphery of the electronic device. The conductive area may be operated as an antenna radiator to transmit and/or receive wireless communication signal by being fed by a wireless communication module.

### SUMMARY

According to an aspect of the disclosure, an electronic device includes: at least one camera; a first conductive pattern separated from the at least one camera by a first distance; a second conductive pattern separated from the at least one camera by a second distance, the second distance being longer than the first distance; and a communication processor configured to transmit a data signal to an external electronic device and configured to receive a control signal from the external electronic device, through the first conductive pattern and the second conductive pattern, wherein the communication processor is further configured to: transmit a first data signal to the external electronic device by controlling the first conductive pattern and the second conductive pattern in a first time period indicated by the control signal transmitted from the external electronic device; transmit a second data signal to the external electronic device by controlling the second conductive pattern in a second time period different from the first time period; and adjust, when the at least one camera is operated in the first time period, a strength of the first data signal to be lower than a preset strength associated with an operation of the at least one camera.

According to an aspect of the disclosure, A method of an electronic device, includes: transmitting, in a first time period indicated by a control signal transmitted from an external electronic device, a first data signal to the external electronic device by controlling a first conductive pattern separated from at least one camera by a first distance, and a second conductive pattern separated from the at least one camera by a second distance that is longer than the first distance; transmitting, in a second time period different from the first time period, a second data signal to the external electronic device by controlling the second conductive pattern; transmitting, in the second time period, the second data signal to the external electronic device by controlling the second conductive pattern; and adjusting, in the first time period, a strength of the first data signal to be lower than a preset strength associated with an operation of the at least one camera.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a block diagram of an electronic device in a network environment according to an embodiment;

FIG. 2 illustrates a block diagram associated with a state of use of an electronic device and an example of a surface of the electronic device according to an embodiment;

FIG. 3 illustrates an example of a signal flowchart between an electronic device and an external electronic device according to an embodiment;

FIG. 4 illustrates an example of an operation cycle in which an electronic device monitors a control signal, according to an embodiment;

FIG. 5 illustrates an example of a flowchart with respect to an operation of an electronic device according to an embodiment; and

FIG. 6 illustrates an example of a flowchart with respect to an operation of an electronic device according to an embodiment.

### DETAILED DESCRIPTION

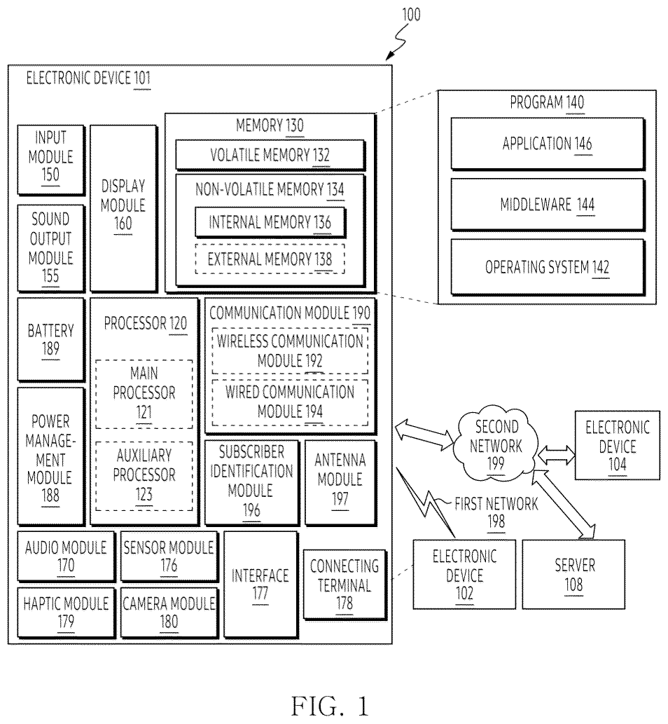

FIG. 1 is a block diagram of an electronic device in a network environment according to an embodiment.

Referring to FIG. 1, the electronic device 101 in the network environment 100 may communicate with an electronic device 102 via a first network 198 (e.g., a short-range wireless communication network), or at least one of an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In some embodiments, at least one of the components (e.g., the connecting terminal 178) may be omitted from the electronic device 101, or one or more other components may be added in the electronic device 101. In some embodiments, some of the components (e.g., the sensor module 176, the camera module 180, or the antenna module 197) may be implemented as a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted boltzmann machine (RBM), a deep belief network (DBN), a bidirectional recurrent deep neural network (BRDNN), deep Q-network or a combination of two or more of those network models but is not limited to those network models. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the intensity of force incurred by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, an HDMI connector, a USB connector, a SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a 5G network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element composed of a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to one or more embodiments, the antenna module 197 may be or correspond to a mmWave antenna module. According to an embodiment, the mmWave antenna module may include a printed circuit board, an RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra-low-latency services using, e.g., distributed computing or mobile edge computing. In another embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

The electronic device according to One or more embodiments may be one of various types of electronic devices. The electronic devices may include, for example, a portable communication device (e.g., a smartphone), a computer device, a portable multimedia device, a portable medical device, a camera, a wearable device, or a home appliance. According to an embodiment of the disclosure, the electronic devices are not limited to those described above.

One or more embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. A singular form of a noun corresponding to an item may include one or more of the things unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). If an element (e.g., a first element) is referred to, with or without the term “operatively” or “communicatively”, as “coupled with,” or “connected with” another element (e.g., a second element), it means that the element may be coupled with the other element directly (e.g., wiredly), wirelessly, or via a third element.

As used in connection with one or more embodiments of the disclosure, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

One or more embodiments as set forth herein may be implemented as software (e.g., the program 140) including one or more instructions that are stored in a storage medium (e.g., internal memory 136 or external memory 138) that is readable by a machine (e.g., the electronic device 101). For example, a processor (e.g., the processor 120) of the machine (e.g., the electronic device 101) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between a case in which data is semi-permanently stored in the storage medium and a case in which the data is temporarily stored in the storage medium.

According to an embodiment, a method according to One or more embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to one or more embodiments, each component (e.g., a module or a program) of the above-described components may include a single entity or multiple entities, and some of the multiple entities may be separately disposed in different components. According to one or more embodiments, one or more of the above-described components may be omitted, or one or more other components may be added. Alternatively or additionally, a plurality of components (e.g., modules or programs) may be integrated into a single component.

In such a case, according to One or more embodiments, the integrated component may still perform one or more functions of each of the plurality of components in the same or similar manner as they are performed by a corresponding one of the plurality of components before the integration. According to one or more embodiments, operations performed by the module, the program, or another component may be carried out sequentially, in parallel, repeatedly, or heuristically, or one or more of the operations may be executed in a different order or omitted, or one or more other operations may be added.

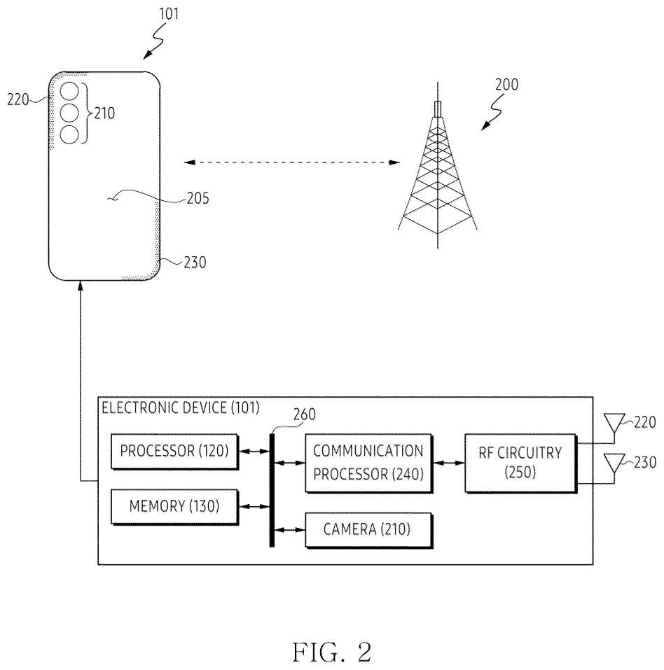

FIG. 2 illustrates a block diagram associated with a state of use of an electronic device and an example of a surface of the electronic device according to an embodiment. An electronic device 101 of FIG. 2 may be an example of the electronic device 101 of FIG. 1. A processor 120 of FIG. 2 may be an example of the processor 120 of FIG. 1. A memory 130 of FIG. 2 may be an example of the memory 130 of FIG. 1. A camera 210 of FIG. 2 may be an example of the camera module 180 of FIG. 1.

Referring to FIG. 2, according to an embodiment, the electronic device 101 may include at least one camera 210. The electronic device 101 may include a first conductive pattern 220 and/or a second conductive pattern 230. For example, the first conductive pattern 220 and/or the second conductive pattern 230 may correspond to at least a portion of the antenna module 197 of FIG. 1.

The electronic device 101 according to an embodiment may transmit a data signal to an external electronic device 200 through the first conductive pattern 220 and/or the second conductive pattern 230. The first conductive pattern 220 and/or the second conductive pattern 230 according to an embodiment may form at least one antenna of the electronic device 101. The external electronic device 200 may include a base station to connect the electronic device 101 through a network (e.g., the second network 199 of FIG. 1).

According to an embodiment, the electronic device 101 may communicate with the external electronic device 200 based on a protocol for a fourth generation wireless communication network (e.g., long term evolution (LET)) and/or another protocol for a fifth generation wireless communication network (e.g., new radio (NR)). For example, the external electronic device 200 may be or correspond to an e-node B (eNB) and/or a next generation node B (gNB). The data signal may be a signal transmitted through the external electronic device 200 to an external electronic device different from the external electronic device 200. The electronic device 101 may receive a control signal from the external electronic device 200 through a conductive pattern different from the first conductive pattern 220 and/or the second conductive pattern 230. The control signal may include information for assigning a time period and/or a frequency range for the electronic device 101 to transmit the data signal to the external electronic device 200. For example, the electronic device 101 may transmit the data signal to the external electronic device 200 based on the information in the control signal based on receiving the control signal from the external electronic device 200. For example, the electronic device 101 may transmit the data signal to the external electronic device 200 through the time period and/or the frequency range included in the information based on the information included in the control signal.

Referring to FIG. 2, according to an embodiment, the electronic device 101 may include at least one of the processor 120, the memory 130, the camera 210, a communication processor 240, RF circuitry 250, the first conductive pattern 220, or the second conductive pattern 230. The processor 120, the memory 130, the camera 210, and the communication processor 240 may be electrically and/or operably coupled with each other by an electrical component such as a bus or interface 260.

Embodiments of the disclosure are not limited to the above embodiment. For example, a portion of hardware components illustrated in FIG. 2 (e.g., at least a portion of the processor 120, the memory 130, the camera 210, the communication processor 240, the RF circuitry 250, the first conductive pattern 220, and/or the second conductive pattern 230) may be included in a single integrated circuit, such as a system on a chip (SoC). A type and/or the number of hardware components included in the electronic device 101 is not limited as illustrated in FIG. 2. For example, the electronic device 101 may include only a portion of the hardware components illustrated in FIG. 2. The processor 120, the memory 130, the communication processor 240, the camera 210, the RF circuitry 250, the first conductive pattern 220, and/or the second conductive pattern 230 are illustrated in a single number, but may be plural.

The processor 120 of the electronic device 101 of FIG. 2 according to an embodiment may correspond to at least a portion of the processor 120 of FIG. 1. The processor 120 according to an embodiment may include a hardware component to process data based on one or more instructions. The hardware component to process the data may include, for example, an arithmetic and logic unit (ALU), a floating point unit (FPU), a field programmable gate array (FPGA), an application processor (AP), and/or a central processing unit (CPU). The number of the processors 120 may be one or more. For example, the processor 120 may have a structure of a multi-core processor such as a dual core, a quad core, or a hexa core. For example, the processor 120 may have a structure of a single core processor such as a single core. However, the disclosure is not limited to the above examples.

The communication processor 240 of the electronic device 101 according to an embodiment may correspond to at least a portion of the auxiliary processor 123 of FIG. 1 and/or the communication module 190 of FIG. 1. For example, the communication processor 240 may be used for a variety of radio access technology (RAT). For example, the communication processor 240 may be used to perform Bluetooth™ communication, fourth generation (4G) technology standard such as the LTE, fifth generation (5G) technology standard, sixth generation (6G) technology standard, wireless facility (WiFi), Bluetooth low energy (BLE), Near field communication (NFC), and/or wireless local area network (WLAN) communication. For example, the communication processor 240 may establish a connection with the external electronic device 200. For example, the electronic device 101 may establish the connection with the external electronic device 200 based on a standard of the fourth generation technology standard such as the LTE or the fifth generation technology standard. For example, the electronic device 101 may receive the control signal from the external electronic device 200 based on mobile communication standards. For example, the electronic device 101 may transmit the data signal to the external electronic device 200 based on the mobile communication standards. In some embodiments, the communication processor 240 is replaced by the processor 120. In some embodiments, the communication processor 240 is included in the processor 120. In some embodiments, the processor 120 may be or correspond to at least one processor; one or more processors that correspond to, for example, the ALU, the FPU, the FPGA, the AP, or the CPU. Also, In some embodiments, the communication processor 240 may be or correspond to at least one processor; one or more processors that correspond to, for example, the ALU, the FPU, the FPGA, the AP, or the CPU.

The electronic device 101 according to an embodiment may include the memory 130. The memory 130 may correspond to the memory 130 of FIG. 1. For example, the memory 130 may store instructions that cause at least one operation of the electronic device 101. For example, the processor 120 may cause the at least one operation of the electronic device 101 when executing instructions stored in the memory 130.

The memory 130 of the electronic device 101 according to an embodiment may include an antenna code. For example, the antenna code may be referred to as an antenna impedance tuner (AIT) code. For example, the antenna code may include information used for impedance matching of the RF circuitry 250 by the processor 120 and/or the communication processor 240.

The electronic device 101 according to an embodiment may include the RF circuitry 250. For example, the RF circuitry 250 may include circuitry to process a signal in a radio frequency range. For example, the RF circuitry 250 may include a radio frequency front end (RFFE) and/or a radio frequency integrated circuit (RFIC). The RFFE and/or the RFIC may convert a signal transmitted from the outside. The RFFE and/or the RFIC may convert a signal transmitted from the electronic device 101 to the outside. The RF circuitry 250 of the electronic device 101 may process the signal in the radio frequency range. For example, the RF circuitry 250 may perform frequency conversion by receiving the signal of the radio frequency range.

According to an embodiment, the RF circuitry 250 of the electronic device 101 may perform the frequency conversion between a signal having a frequency of an intermediate frequency range (e.g., approximately 8 GHz) and a signal having a frequency of the radio frequency range. For example, the radio frequency range may be at least a portion of a frequency of approximately 24 GHz to approximately 40 GHz, for example, as a frequency range of a radio signal transmitted or received by the first conductive pattern 220 and/or the second conductive pattern 230. The RF circuitry 250 of the electronic device 101 according to an embodiment may perform the impedance matching associated with the first conductive pattern 220 and/or the second conductive pattern 230, connected to the RF circuitry 250.

The RF circuitry 250 may adjust a gain between an electrical signal outputted from the RF circuitry 250 and the data signal outputted from the first conductive pattern 220 and/or the second conductive pattern 230, by reducing reflection loss of the first conductive pattern 220 and/or the second conductive pattern 230 while the electrical signal is applied to the first conductive pattern 220 and/or the second conductive pattern 230.

The RF circuitry 250 according to an embodiment may transmit the data signal. For example, the RF circuitry 250 may transmit the data signal generated by the communication processor 240. For example, when transmitting the signal, the RF circuitry 250 may convert a baseband signal generated by the communication processor 240 into a radio frequency (RF) signal of approximately 700 MHz to approximately 3 GHz.

When transmitting the signal, the RF circuitry 250 according to an embodiment may convert the baseband signal generated by the communication processor 240 into a RF signal (hereinafter, a 5G sub6 RF signal) of a Sub6 band (e.g., approximately 6 GHz or lower). The RF circuitry 250 may convert the preprocessed 5G Sub6 RF signal into the baseband signal for processing by the communication processor 240.

When transmitting the signal, the RF circuitry 250 according to an embodiment may convert the baseband signal generated by the communication processor 240 into a RF signal (hereinafter, a 5G Above6 RF signal) of 5G Above6 band (e.g., approximately 6 GHz to approximately 60 GHz). For example, the RF circuitry 250 may include an amplifier, a transmitter, a receiver, or a synthesizer. However, it is not limited thereto.

The electronic device 101 according to an embodiment may transmit the data signal to the external electronic device 200 through a frequency band such as N77, N78, N41, N3, N1, and/or N66. For example, the N77 frequency range may be set based on a frequency range of approximately 3.3 GHz to approximately 3.8 GHz. For example, the N78 frequency range may be set based on a frequency range of approximately 3.3 GHz to approximately 3.8 GHz. For example, the N41 frequency range may be set based on a frequency range of approximately 2,496 MHz to approximately 2,690 MHz. For example, the N3 frequency range may be set based on a frequency range of approximately 1,710 MHz to approximately 1,785 MHz. For example, the N1 frequency range may be set based on a frequency range of approximately 1,920 MHz to approximately 1,980 MHz. For example, the N66 frequency range may be set based on a frequency range of approximately 1,710 MHz to approximately 1,780 MHz. However, it is not limited thereto.

The RF circuitry 250 according to an embodiment may include impedance matching circuitry. For example, the impedance matching circuitry may be connected to the first conductive pattern 220 through switches. For example, the impedance matching circuitry may be connected to the second conductive pattern 230 through the switches. The impedance matching circuitry may include capacitors to perform impedance matching of the first conductive pattern 220. The impedance matching circuitry may include inductors to perform the impedance matching of the first conductive pattern 220. The impedance matching circuitry may include capacitors to perform impedance matching of the second conductive pattern 230. The impedance matching circuitry may include inductors to perform the impedance matching of the second conductive pattern 230.

The communication processor 240 according to an embodiment may control switches that may be connected to the impedance matching circuitry and the first conductive pattern 220 based on the antenna code stored in the memory 130. The communication processor 240 may control a resonance frequency of the first conductive pattern 220 by controlling the impedance matching circuitry. For example, the communication processor 240 may perform the impedance matching of the first conductive pattern 220 based on the capacitors by controlling the switches. For example, the communication processor 240 may perform the impedance matching of the first conductive pattern 220 based on the inductors by controlling the switches.

The communication processor 240 according to an embodiment may transmit at least one of a first data signal and a second data signal. For example, the communication processor 240 may adjust a frequency corresponding to the at least one of the first data signal or the second data signal based on the RF circuitry 250.

The communication processor 240 according to an embodiment may control switches that may be connected to the impedance matching circuitry and the second conductive pattern 230 based on the antenna code stored in the memory 130. For example, the communication processor 240 may perform the impedance matching of the second conductive pattern 230 based on the capacitors by controlling the switches. For example, the communication processor 240 may control a resonance frequency of the second conductive pattern 230 by controlling the impedance matching circuitry. For example, the communication processor 240 may perform the impedance matching of the second conductive pattern 230 based on the inductors by controlling the switches.

The communication processor 240 of the electronic device 101 according to an embodiment may receive the control signal transmitted from the external electronic device 200. For example, the control signal may include a signal transmitted through a control channel of a physical layer, such as a physical downlink control channel (PDCCH) transmitted from the external electronic device 200. For example, the communication processor 240 may identify the first time period indicated by the control signal. For example, the communication processor 240 may control all of the first conductive pattern 220 and the second conductive pattern 230 within the first time period. The communication processor 240 may transmit the first data signal to the external electronic device 200 by controlling all of the first conductive pattern 220 and the second conductive pattern 230. For example, the first data signal may include a signal associated with a 4G frequency range and a signal associated with a 5G frequency range. For example, the control signal transmitted from the external electronic device 200 may include information associated with a frequency range of the data signal transmitted by the electronic device 101 to the external electronic device 200 and/or information associated with a time period to transmit the data signal. For example, the control signal may include information for assigning the frequency range to transmit the data signal by the electronic device 101. For example, the control signal may include information for assigning the time period for the electronic device 101 to transmit the data signal.

The communication processor 240 of the electronic device 101 according to an embodiment may monitor the control signal. For example, the communication processor 240 may identify the control signal at a preset period (e.g., approximately 0.5 ms). The communication processor 240 according to an embodiment may receive the control signal based on all of a plurality of wireless communication protocols supported by the external electronic device 200 as the base station. For example, the communication processor 240 may receive the control signal based on the preset period associated with an exchange of the control signal to communicate with the external electronic device 200.

According to an embodiment, the communication processor 240 may adjust the preset period. For example, the communication processor 240 may receive the control signal including other data (or information) different from data (or information) indicating the first time period. The communication processor 240 may increase the preset period for monitoring of the control signal. For example, the communication processor 240 may increase the preset period for monitoring of the control signal, based on receiving the control signal. For example, the other data different from the data indicating the first time period may include blank data. For example, the communication processor 240 may increase the preset period based on identifying the blank data.

The communication processor 240 according to an embodiment may adjust a size of the first data signal transmitted through the first conductive pattern 220 within the first time period. For example, when transmitting the first data signal through the first conductive pattern 220 within the first time period, the communication processor 240 may adjust a strength of the first data signal to be lower than a designated intensity associated with driving of the at least one camera 210. For example, a preset strength associated with driving of the at least one camera 210 may be associated with a strength of generating frequency interference between the at least one camera 210 and the first data signal. For example, the preset strength may be heuristically adjusted to reduce image degradation of the at least one camera 210 by the frequency interference.

The communication processor 240 of the electronic device 101 according to an embodiment may control the second conductive pattern 230 among the first conductive pattern 220 and the second conductive pattern 230 within the second time period different from the first time period. For example, within the second time period, the communication processor 240 may selectively activate the second conductive pattern 230 among the first conductive pattern 220 and the second conductive pattern 230. Since the second conductive pattern 230 is selectively activated, transmission of the data signal based on the first conductive pattern 220 may be at least temporarily ceased within the second time period. For example, the communication processor 240 may transmit the second data signal to the external electronic device 200 by controlling the second conductive pattern 230 within the second time period. For example, the second data signal may include the signal associated with the 5G frequency range.

The communication processor 240 according to an embodiment may transmit a third data signal and a fourth data signal, included in the first data signal. For example, the communication processor 240 may transmit the third data signal included in the first data signal to the external electronic device 200 based on a first radio access technology (RAT). For example, the first RAT may be referred to as the LTE and/or the fourth generation technology standard. For example, the communication processor 240 may transmit the fourth data signal included in the first data signal to the external electronic device 200 based on a second RAT. For example, the second RAT may be referred to as the fifth generation technology standard. For example, the communication processor 240 may transmit the third data signal based on the first RAT to the external electronic device 200 through the second conductive pattern 230. The communication processor 240 may transmit the fourth data signal based on the second RAT to the external electronic device 200 through the first conductive pattern 220. For example, the communication processor 240 may transmit the third data signal based on the first RAT and the fourth data signal based on the second RAT within the first time period.

The communication processor 240 according to an embodiment may transmit the third data signal and/or the fourth data signal through a different frequency range. For example, the communication processor 240 may transmit the third data signal through a second frequency range within a first frequency range. For example, the communication processor 240 may transmit the fourth data signal through a third frequency range within the first frequency range. The first frequency range may include a frequency range for the fourth generation technology standard and a frequency range for the fifth generation technology standard. The third frequency range may correspond to the frequency range for the fourth generation technology standard. The third frequency range may correspond to the frequency range for the fifth generation technology standard. For example, the third frequency range may be a frequency range higher than the second frequency range.

The processor 120 of the electronic device 101 according to an embodiment may identify whether to drive the at least one camera 210. For example, the processor 120 may transmit information associated with driving of the at least one camera 210 to the communication processor 240 based on identifying whether to drive the at least one camera 210. The communication processor 240 may receive information that the at least one camera 210 is driven. The communication processor 240 may control all of the first conductive pattern 220 and the second conductive pattern 230 while the at least one camera 210 is driven. The communication processor 240 may transmit the first data signal to the external electronic device 200 through all of the first conductive pattern 220 and the second conductive pattern 230. The communication processor 240 may adjust the strength of the first data signal transmitted from the first conductive pattern 220 to be lower than the preset strength while transmitting the first data signal. For example, the preset strength may include a frequency associated with driving of the at least one camera 210 and a strength that causes a frequency interference.

The communication processor 240 according to an embodiment may transmit the second data signal to the external electronic device 200 through the second conductive pattern 230 within the second time period different from the first time period. For example, when receiving information that the at least one camera 210 is driven from the processor 120, the communication processor 240 may transmit the second data signal to the external electronic device 200 through the second conductive pattern 230. When receiving information that the at least one camera 210 is driven from the processor 120, the communication processor 240 may transmit the second data signal to the external electronic device 200 by controlling the second conductive pattern 230. When transmitting the second data signal, the communication processor 240 may transmit the second data signal by adjusting a strength to be higher than or equal to the preset strength.

As described above, the electronic device 101 according to an embodiment may adjust the strength of the first data signal when transmitting the first data signal through the first conductive pattern 220 and the second conductive pattern 230. The electronic device 101 may transmit the first data signal to the external electronic device 200 by adjusting the strength of the first data signal to be lower than the preset strength. The electronic device 101 may reduce a noise that may occur while the at least one camera 210 is driven by adjusting the strength of the first data signal to a strength to be lower than the preset strength and transmitting the first data signal.

As described above, the electronic device 101 according to an embodiment may transmit the second data signal to the external electronic device 200 by adjusting the second signal to the preset strength or more. The electronic device 101 may increase a received signal strength indicator (RSSI) of the external electronic device 200 by adjusting a strength of the second data signal to the preset strength or more and transmitting the second data signal through the second conductive pattern 230. The electronic device 101 may reduce loss of the data signal transmitted from the electronic device 101 to the external electronic device 200 by increasing the RSSI of the external electronic device.

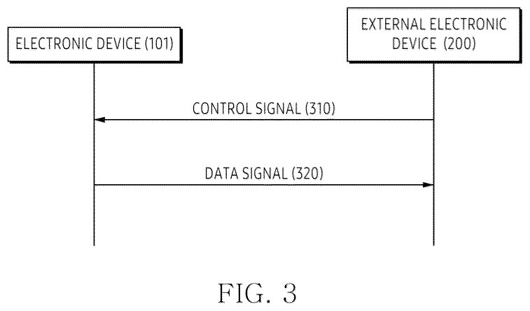

FIG. 3 illustrates an example of a signal flowchart between an electronic device and an external electronic device according to an embodiment. An electronic device 101 of FIG. 3 may be an example of the electronic device 101 of FIGS. 1 and/or 2. An external electronic device 200 of FIG. 3 may be an example of the external electronic device 200 of FIG. 2. Operations of FIG. 3 may be performed by the communication processor 240 of FIG. 2.

Referring to FIG. 3, in an operation 310, according to an embodiment, the electronic device 101 may receive a control signal from the external electronic device 200. For example, the electronic device 101 may receive the control signal through a conductive pattern. The conductive pattern may be referred to as the antenna module 197 of FIG. 1. For example, the electronic device 101 may communicate with the external electronic device 200 based on all of a plurality of wireless communication protocols supported by the external electronic device 200 that is a base station. For example, communicating of the electronic device 101 with the external electronic device 200 may be referred to as E-UTRA NR dual connectivity (ENDC). For example, the ENDC may include the electronic device transmitting a data signal through a fourth generation technology standard and a fifth generation technology standard.

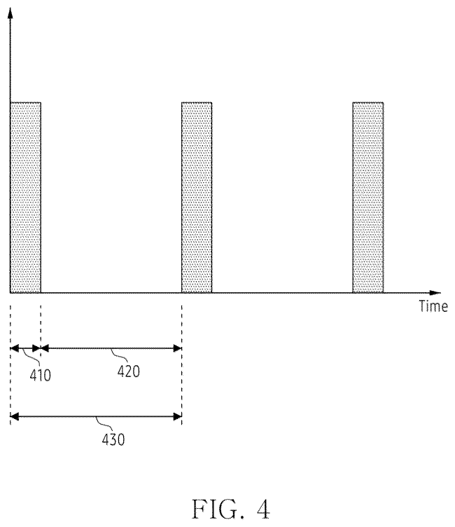

For example, the ENDC may be associated with transmitting the data signal to the external electronic device 200 or receiving the data signal from the external electronic device 200 based on a plurality of the mobile communication standards. The electronic device 101 may monitor the control signal at a preset period (e.g., approximately 0.5 ms). An operation in which the electronic device 101 monitors the control signal at the preset period will be described later with reference to FIG. 4.

The electronic device 101 according to an embodiment may obtain information included in the control signal. For example, the control signal may include information associated with a frequency range that may be used when the electronic device 101 transmits the data signal to the external electronic device 200. For example, the control signal may include information associated with a time band that the electronic device 101 may use when transmitting the data signal to the external electronic device 200. For example, the control signal may include the information for assigning the frequency range in which the electronic device 101 may transmit the data signal. For example, the control signal may include the information for assigning the time band in which the electronic device 101 may transmit the data signal.

In an operation 320, the electronic device 101 according to an embodiment may transmit the data signal to the external electronic device 200. For example, the electronic device 101 may transmit the data signal to the external electronic device 200 based on a communication processor (e.g., the communication processor 240 of FIG. 2) included in the electronic device 101. The electronic device 101 may transmit the data signal to the external electronic device 200 by preprocessing the data signal through RF circuitry (e.g., the RF circuitry of FIG. 2) included in the electronic device 101. For example, the electronic device 101 may transmit the data signal to the external electronic device 200 by adjusting a frequency of the data signal through impedance matching circuitry included in the RF circuitry.

According to an embodiment, the electronic device 101 may transmit the data signal to the external electronic device 200 through a first conductive pattern (e.g., the first conductive pattern 220 of FIG. 2) and/or a second conductive pattern (e.g., the second conductive pattern 230 of FIG. 2). The electronic device 101 may adjust the frequency of the data signal transmitted through the first conductive pattern and/or the second conductive pattern based on an antenna code stored in a memory (e.g., the memory 130 of FIG. 1 and/or FIG. 2) of the electronic device 101.

The electronic device 101 according to an embodiment may transmit a first data signal to the external electronic device 200 through the first conductive pattern. The electronic device 101 according to an embodiment may transmit a second data signal to the external electronic device 200 through the second conductive pattern. The first data signal and/or the second data signal may be transmitted based on a frequency range assigned by the external electronic device 200.

According to an embodiment, the electronic device 101 may receive information capable of transmitting the data signal from the external electronic device 200 through a first frequency range (e.g., a frequency range in which LTE is transmitted, and a frequency range in which 5G is transmitted). The electronic device 101 may transmit the first data signal using all of the first conductive pattern and the second conductive pattern based on reception of the information. The electronic device 101 may adjust a strength of a signal transmitted through the first conductive pattern to be lower than a preset strength while transmitting the first data signal. For example, the first conductive pattern may transmit a data signal associated with 5G when transmitting the first data signal. The second conductive pattern may transmit a data signal associated with LTE when transmitting the second data signal. For example, the electronic device 101 may transmit a third data signal included in the first data signal through a second frequency range (e.g., a frequency range capable of transmitting LTE data) within the first frequency range. For example, the electronic device 101 may transmit a fourth data signal included in the first data signal through a third frequency range (e.g., a frequency range capable of transmitting 5G data) within the first frequency range. For example, the third frequency range may be higher than the second frequency range.

According to an embodiment, the electronic device 101 may transmit the third data signal and the fourth data signal to the external electronic device 200 while at least one camera (e.g., the at least one camera 210 of FIG. 2) is driven. The electronic device 101 may adjust a strength of the fourth data signal when transmitting the third data signal and the fourth data signal. For example, the electronic device 101 may transmit the fourth data signal to the external electronic device 200 by powering backoff the fourth data signal. The electronic device 101 may reduce a noise that may occur during a camera operation of the electronic device 101 by powering backoff and transmitting the fourth data signal.

FIG. 4 illustrates an example of an operation cycle in which an electronic device monitors a control signal, according to an embodiment. The electronic device of FIG. 4 may be an example of the electronic device 101 of FIGS. 1, 2, and/or 3. Operations of FIG. 4 may be performed by the communication processor 240 of FIG. 2 and/or the processor 120 of FIG. 2.

Referring to FIG. 4, the electronic device according to an embodiment may identify the control signal transmitted from an external electronic device (e.g., the external electronic device 200 of FIGS. 2, and/or 3) at a preset period 430. For example, the external electronic device may include a base station that may include an eNB for a fourth generation technology standard. The base station may include a gNB for a 5th generation technology standard. For example, the preset period may be approximately 0.5 ms. However, the disclosure is not limited to the example of the preset period.

The electronic device according to an embodiment may communicate with the external electronic device based on all of a plurality of wireless communication protocols supported by the external electronic device that is the base station. The electronic device may receive the control signal based on the preset period 430 associated with an exchange of the control signal.

The electronic device according to an embodiment may receive the control signal indicating a first time period 410. The electronic device may transmit a data signal to the external electronic device based on receiving the control signal indicating the first time period 410. For example, the electronic device may obtain information included in the control signal indicating the first time period 410. The information may include a frequency range assigned to the data signal transmitted from the electronic device to the external electronic device. For example, the information may include a time band assigned to the data signal transmitted from the electronic device to the external electronic device. For example, the electronic device may receive information to transmit a data signal associated with the fourth generation technology standard and/or a data signal associated with the fifth generation technology standard within the first time period 410. For example, the electronic device may maintain the preset period 430 based on obtaining the data signal associated with the fourth generation technology standard within the first time period 410. The electronic device may transmit the data signal based on a first conductive pattern and a second conductive pattern included in the electronic device while maintaining the preset period 430.

The electronic device according to an embodiment may transmit the data signal to the external electronic device through the first conductive pattern and the second conductive pattern. For example, the first conductive pattern may be separated from at least one camera (e.g., the at least one camera 210 of FIG. 2) included in the electronic device by a first distance. For example, the second conductive pattern may be separated from the at least one camera by a second distance longer than the first distance.

According to an embodiment, the electronic device may identify the first time period indicated by the control signal transmitted from the external electronic device. For example, the electronic device may receive the control signal to control all of the first conductive pattern and the second conductive pattern within the first time period. The electronic device 101 may use all of the first conductive pattern and the second conductive pattern. The electronic device 101 may transmit a first data signal through the first conductive pattern and the second conductive pattern. For example, transmitting the first data signal may include transmitting data using the fourth generation technology standard and the fifth generation technology standard. For example, the operation of transmitting the first data signal may be referred to as or may correspond to ENDC. For example, the ENDC may include the electronic device transmitting the data signal through the fourth generation technology standard and the fifth generation technology standard. For example, the electronic device may adjust a strength of the first data signal transmitted from the first conductive pattern within the first time period. For example, the electronic device may adjust the strength of the first data signal to be lower than a preset strength associated with driving of the at least one camera (e.g., the at least one camera 210 of FIG. 2). For example, the electronic device may transmit the first data signal adjusted to be lower than the preset strength associated with driving of the at least one camera to the external electronic device.

The electronic device according to an embodiment may transmit a second data signal to the external electronic device by controlling the second conductive pattern within the second time period 420. For example, the second data signal may include a signal transmitted through the fifth generation technology standard.

The electronic device according to an embodiment may adjust the preset period 430. For example, the electronic device may receive the control signal including another data (or information) different from data (or information) indicating the first time period 410. For example, the control signal including the other data different from the data indicating the first time period 410 may not include the data indicating the first time period 410. For example, the electronic device may increase the preset period 430 for monitoring of the control signal based on receiving the control signal including the other data different from the data indicating the first time period 410.

The electronic device according to an embodiment may identify an end time point of the first time period 410. For example, the electronic device may identify the end time point of the first time period 410 based on data (or information) included in the control signal transmitted from the external electronic device. For example, the electronic device may identify the end time point of the first time period 410 based on an LTE long term evolution radio resource control (RRC) column. For example, the electronic device may identify the end time point of the first time period 410 based on an uplink dedicated control channel (UL DCCH), an uplink common control channel (UL CCCH), a downlink dedicated control channel (DL DCCH), a downlink common control channel (DL CCCH), an uplink shared channel (UL SCH), and/or a downlink shared channel (DL SCH) included in the LTE RRC. However, it is not limited thereto.

As described above, the electronic device according to an embodiment may adjust the preset period 430 based on the control signal including the data different from the data indicating the first time period 410. The electronic device may increase battery efficiency by adjusting the preset period 430.

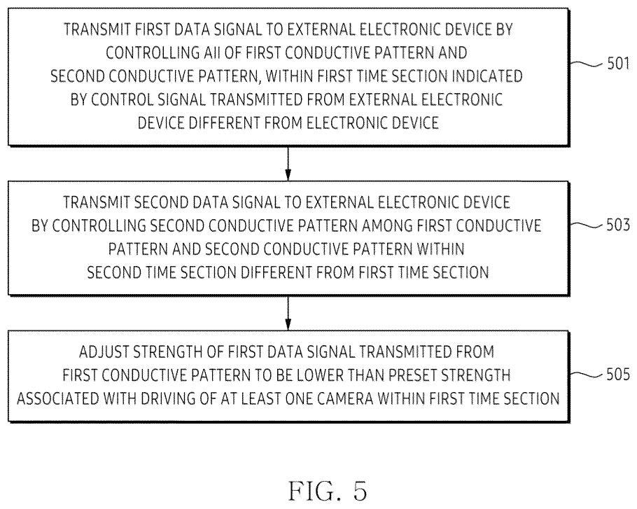

FIG. 5 illustrates an example of a flowchart with respect to operations performed by an electronic device according to an embodiment. The electronic device of FIG. 5 may be an example of the electronic device 101 of FIGS. 1, 2, and/or 3 and/or the electronic device of FIG. 4. Operations of FIG. 5 may be performed by the processor 120 of FIGS. 1 and/or 2. The operations of FIG. 5 may be performed by the communication processor 240 of FIG. 2.

According to an embodiment, the electronic device may include a first conductive pattern (e.g., the first conductive pattern 220 of FIG. 2) and/or a second conductive pattern (e.g., the second conductive pattern 230 of FIG. 2). For example, the first conductive pattern may be formed by being separated from at least one camera (e.g., the at least one camera 210 of FIG. 2) positioned on a surface (e.g., the surface 205 of FIG. 2) of the electronic device by a first distance. For example, the second conductive pattern may be formed by being separated from the at least one camera by a second distance. For example, the second distance may be longer than the first distance.

Referring to FIG. 5, in an operation 501, the electronic device according to an embodiment may receive a control signal transmitted from an external electronic device (e.g., the external electronic device 200 of FIG. 2) different from the electronic device. The electronic device may control all of the first conductive pattern and the second conductive pattern within a first time section (e.g., the first time period 410 of FIG. 4) indicated by the control signal. The electronic device may transmit a first data signal to the external electronic device by controlling all of the first conductive pattern and the second conductive pattern. For example, the first data signal may include a signal transmitted based on a fourth generation technology standard and a fifth generation technology standard.

The electronic device according to an embodiment may adjust at least a portion of the first data signal to a frequency matched to the fourth generation technology standard based on impedance matching circuitry. The electronic device may adjust the at least a portion of the first data signal to a frequency matched to the fifth generation technology standard based on the impedance matching circuitry. The electronic device may transmit a signal converted into a frequency matched to each of the fourth generation technology standard and the fifth generation technology standard to the external electronic device.

In an operation 503, according to an embodiment, the electronic device may control the second conductive pattern within a second time section (e.g., the second time period 420 of FIG. 4) different from the first time section. For example, the electronic device may transmit a second data signal to the external electronic device by controlling the second conductive pattern among the first conductive pattern and the second conductive pattern within the second time section. For example, the second data signal may include a signal transmitted based on the fifth generation technology standard. For example, the electronic device may adjust the second data signal to the frequency matched to the fifth generation technology standard based on the impedance matching circuitry. The electronic device may transmit the second data signal adjusted to the frequency matched to the fifth generation technology standard to the external electronic device.

In an operation 505, the electronic device according to an embodiment may adjust the strength of the data signal transmitted from the first conductive pattern within the first time section. For example, the electronic device may identify driving of the at least one camera (e.g., the at least one camera 210 of FIG. 2) based on a processor (e.g., the processor 120 of FIG. 1 and/or FIG. 2). For example, the electronic device may adjust a strength of the first data signal while identifying driving of the at least one camera. For example, the electronic device may adjust the strength of the first data signal to be lower than a preset strength associated with driving of the at least one camera. The electronic device, for example, may transmit the first data signal to the external electronic device by adjusting the strength of the first data signal transmitted from the first conductive pattern to be lower than the preset strength associated with driving of the at least one camera within the first time section.

As described above, the electronic device according to an embodiment may adjust the strength of the first data signal while the at least one camera is driven within the first time section. The electronic device may adjust the strength of the first data signal to be lower than the preset strength associated with the driving of the at least one camera. The electronic device may reduce a noise of the at least one camera that may occur based on the first data signal by transmitting the first data signal adjusted to be lower than the preset strength.

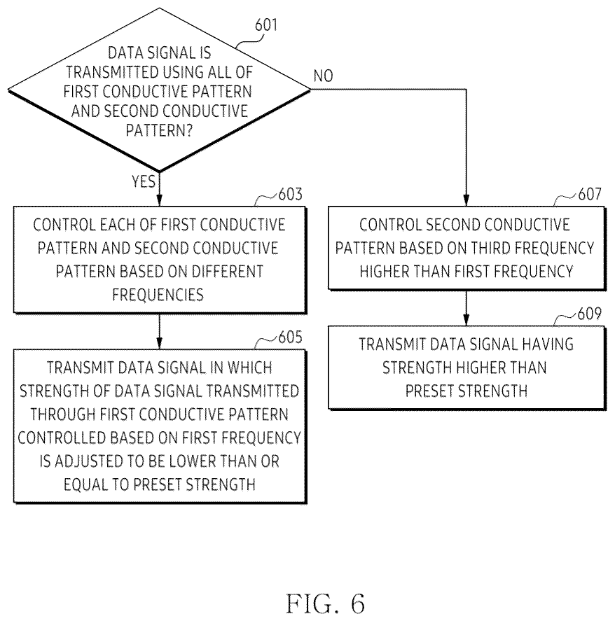

FIG. 6 illustrates an example of a flowchart with respect to an operation of an electronic device according to an embodiment. The electronic device of FIG. 6 may be an example of the electronic device 101 of FIG. 1, 2, or 3, the electronic device of FIGS. 4, and/or 5. Operations of FIG. 6 may be performed by the processor 120 of FIGS. 1 and/or 2. The operations of FIG. 6 may be performed by the communication processor 240 of FIG. 2.

According to an embodiment, the electronic device may include a first conductive pattern (e.g., the first conductive pattern 220 of FIG. 2) and/or a second conductive pattern (e.g., the second conductive pattern 230 of FIG. 2). For example, the first conductive pattern may be formed by being separated from at least one camera (e.g., the at least one camera 210 of FIG. 2) positioned on a surface (e.g., the surface 205 of FIG. 2) of the electronic device by a first distance. For example, the second conductive pattern may be formed by being separated from the at least one camera by a second distance. For example, the second distance may be longer than the first distance.

Referring to FIG. 6, in an operation 601, the electronic device according to an embodiment may identify whether to transmit a data signal using all of the first conductive pattern and the second conductive pattern. For example, the electronic device may identify a first state in which the data signal is transmitted using all of the first conductive pattern and the second conductive pattern. For example, the electronic device may identify a second state in which the data signal is transmitted using the second conductive pattern among the first conductive pattern and the second conductive pattern. For example, the electronic device may transmit the data signal to an external electronic device through the first conductive pattern and/or the second conductive pattern in the first state and/or the second state based on a control signal transmitted from the external electronic device.

In a case that the electronic device transmits the data signal using all of the first conductive pattern and the second conductive pattern (601, “YES”), in an operation 603, according to an embodiment, the electronic device may control each of the first conductive pattern and the second conductive pattern based on different frequencies. For example, the electronic device may control each of the first conductive pattern and the second conductive pattern based on the different frequencies in the first state of transmitting the data signal using all of the first conductive pattern and the second conductive pattern.

For example, the electronic device may perform impedance matching of each of the first conductive pattern and the second conductive pattern based on RF circuitry (e.g., the RF circuitry of FIG. 2) included in the electronic device. For example, the RF circuitry may be connected to the first conductive pattern through switches. For example, the RF circuitry may include capacitors to perform the impedance matching of the first conductive pattern. For example, the RF circuitry may include inductors to perform the impedance matching of the first conductive pattern. For example, the RF circuitry may be connected to the second conductive pattern through the switches. For example, the RF circuitry may include the capacitors to perform the impedance matching of the second conductive pattern. For example, the RF circuitry may include the inductors to perform the impedance matching of the second conductive pattern.

The electronic device according to an embodiment may control the switches capable of connecting the RF circuitry and the first conductive pattern. For example, the electronic device may control the switches based on an antenna code stored in a memory (e.g., the memory 130 of FIGS. 1 and/or 2). For example, the electronic device may perform the impedance matching of the first conductive pattern based on the capacitors and/or the inductors by controlling the switches. The electronic device according to an embodiment may control the switches capable of connecting the RF circuitry and the second conductive pattern. For example, the electronic device may control the switches based on the antenna code stored in the memory. For example, the electronic device may perform the impedance matching of the second conductive pattern based on the capacitors and/or the inductors by controlling the switches. For example, the electronic device may control each of the first conductive pattern and the second conductive pattern based on the different frequency by performing the impedance matching.

In an operation 605, the electronic device according to an embodiment may adjust a strength of the data signal transmitted through the first conductive pattern controlled based on a first frequency. For example, the electronic device may control the first conductive pattern based on the first frequency and control the second conductive pattern based on a second frequency. For example, the first frequency may include a frequency higher than the second frequency.

According to an embodiment, the electronic device may identify the first state in which the first frequency of the first conductive pattern is higher than the second frequency of the second conductive pattern. The electronic device may adjust the strength of the data signal transmitted through the first conductive pattern controlled based on the first frequency in the first state. The electronic device may adjust the strength of the data signal to be lower than or equal to a preset strength. For example, the preset strength may include a strength associated with driving of the at least one camera of the electronic device. For example, the preset strength may include a strength at which the first conductive pattern and the at least one camera may cause frequency interference. For example, the electronic device may transmit the data signal to the external electronic device by adjusting the strength of the data signal transmitted through the first conductive pattern to be lower than the preset strength.

The electronic device according to an embodiment may adjust the strength of the data signal based on information associated with driving of the at least one camera included in the electronic device. For example, while the at least one camera is driven, the electronic device may transmit the data signal to the external electronic device by adjusting the strength of the data signal transmitted through the first conductive pattern to be lower than the preset strength. As described above, the electronic device according to an embodiment may reduce a noise of the at least one camera by adjusting the strength of the data signal transmitted through the first conductive pattern to be lower than the preset strength.

In a case that the electronic device does not transmit the data signal using all of the first conductive pattern and the second conductive pattern (601, “NO”), in an operation 607, according to an embodiment, the electronic device may identify the second state different from the first state. For example, the electronic device may control the second conductive pattern based on a third frequency within the second state different from the first state. For example, the third frequency may include a frequency higher than the first frequency.

In an operation 609, the electronic device according to an embodiment may transmit a data signal having a strength higher than the preset strength within the second state. For example, within the second state, the electronic device may control the second conductive pattern based on the third frequency. For example, within the second state, the electronic device may transmit the data signal having the strength higher than the preset strength through the second conductive pattern controlled based on the third frequency.

According to an embodiment, the electronic device may adjust a strength of the data signal transmitted through the second conductive pattern while the at least one camera is driven. For example, the electronic device may transmit the data signal to the external electronic device by adjusting the strength of the data signal transmitted through the second conductive pattern to be higher than or equal the preset strength while the at least one camera is driven.

As described above, the electronic device according to an embodiment may reduce loss of the data signal transmitted to the external electronic device by adjusting the strength of the data signal transmitted through the second conductive pattern to be higher than or equal the preset strength and transmitting the data signal while the at least one camera is driven. For example, the electronic device may increase a RSSI of the external electronic device by adjusting the strength of the data signal to be higher than or equal to the preset strength and transmitting the data signal. The electronic device may reduce the loss of the data signal transmitted from the electronic device to the external electronic device by increasing the RSSI of the external electronic device.

According to an embodiment, an electronic device (e.g., the electronic device 101 of FIGS. 1, 2, and/or 3) may comprise a housing, at least one camera (e.g., the camera 210 of FIG. 2) positioned on a surface of the housing, a first conductive pattern (e.g., the first conductive pattern 220 of FIG. 2) separated from the at least one camera by a first distance, a second conductive pattern (e.g., the second conductive pattern 230 of FIG. 2) separated from the at least one camera by a second distance longer than the first distance, and a communication processor (e.g., the communication processor 240 of FIG. 2) to transmit a data signal to an external electronic device (e.g., the external electronic device 200 of FIG. 2) different from the electronic device or to receive a control signal from the external electronic device 200, through the first conductive pattern and the second conductive pattern. The communication processor may be configured to transmit a first data signal to the external electronic device by controlling all of the first conductive pattern and the second conductive pattern in a first time period (e.g., the first time period 410 of FIG. 4) indicated by the control signal transmitted from the external electronic device different from the electronic device. The communication processor may be configured to transmit a second data signal to the external electronic device by controlling the second conductive pattern among the first conductive pattern and the second conductive pattern in a second time period (e.g., the second time period 420 of FIG. 4) different from the first time period. The communication processor may be configured to adjust, while the at least one camera is driven in the first time period, a strength of the first data signal transmitted from the first conductive pattern to be lower than a preset strength associated with driving of the at least one camera.

According to an embodiment, the communication processor may be configured to monitor the control signal by a preset period (e.g., the preset period 430 of FIG. 4).

According to an embodiment, the communication processor may be configured to receive the control signal based on the preset period associated with exchanging of the control signal to communicate with the external electronic device based on all of a plurality of wireless communication protocols supported by the external electronic device which is a base station.

According to an embodiment, the communication processor may be configure to increase the preset period to monitor the control signal based on receiving the control signal including another data different from data indicating the first time period.

According to an embodiment, the electronic device may comprise radio frequency (RF) circuitry (e.g., the RF circuitry 250 of FIG. 2). The communication processor may be configured to adjust a frequency corresponding to at least one of the first data signal or the second data signal based on the RF circuitry when transmitting the at least one of the first data signal or the second data signal.

According to an embodiment, the electronic device may comprise memory (e.g., the memory 130 of FIGS. 1 and/or 2). The RF circuitry is connected to the first conductive pattern through switches, and comprises capacitors to perform impedance matching of the first conductive pattern. The communication processor may be configured to perform the impedance matching of the first conductive pattern based on the capacitors by controlling the switches based on an antenna code stored in the memory.

According to an embodiment, the first data signal may comprise a third data signal and a fourth data signal. The communication processor may be configured to transmit the third data signal included in the first data signal, to the external electronic device, based on a first radio access technology (RAT). The communication processor may be configured to transmit the fourth data signal included in the first data signal, to the external electronic device, based on a second RAT.

According to an embodiment, the communication processor may be configured to transmit the third data signal through a second frequency range within a first frequency range. The communication processor may be configured to transmit the fourth data signal through a third frequency range higher than the second frequency range within the first frequency range.

According to an embodiment, the electronic device may comprise a processor (e.g., the processor 120 of FIG. 1 and/or FIG. 2). The processor may be configured to transmit information associated with whether to drive the at least one camera, to the communication processor.

According to an embodiment, the communication processor may be configured to adjust, while transmitting the first data signal to the external electronic device, a strength of the first data signal transmitted from the first conductive pattern to be lower than the preset strength, by controlling all of the first conductive pattern and the second conductive pattern when receiving information that the at least one camera is driven from the processor.

As described above, according to an embodiment, the electronic device may reduce loss of the data signal transmitted to the external electronic device by adjusting a strength of the data signal transmitted through the second conductive pattern to be higher than or equal the preset strength while the at least one camera is driven. For example, the electronic device may increase a received signal strength indicator (RSSI) of the external electronic device by adjusting the strength of the data signal to be higher than or equal to the preset strength and transmitting the data signal. The electronic device may reduce the loss of the data signal transmitted from the electronic device to the external electronic device by increasing the RSSI of the external electronic device.

According to an embodiment, the communication processor may be configured to transmit the second data signal, to the external electronic device, by controlling the second conductive pattern when receiving the information that the at least one camera is driven from the processor.

As described above, according to an embodiment, a method of an electronic device (e.g., the electronic device 101 of FIGS. 1, 2, and/or 3) may include transmitting, in a first time period (e.g., the first time period 410 of FIG. 4) indicated by a control signal transmitted from an external electronic device (e.g., the external electronic device 200 of FIG. 2) different from the electronic device, a first data signal to the external electronic device by controlling all of a first conductive pattern (e.g., the second conductive pattern 230 of FIG. 2) separated from at least one camera (e.g., the camera 210 of FIG. 2) positioned on a surface of a housing by a first distance, and a second conductive pattern (e.g., the second conductive pattern 230 of FIG. 2) separated from the at least one camera by a second distance longer than the first distance. The method of an electronic device may comprise transmitting, in a second time period different from the first time period, a second data signal to the external electronic device by controlling the second conductive pattern among the first conductive pattern and the second conductive pattern. The method of an electronic device may comprise transmitting, in the second time period different from the first time period, the second data signal to the external electronic device by controlling the second conductive pattern among the first conductive pattern and the second conductive pattern. The method of an electronic device may comprise adjusting, in the first time period, a strength of the data signal transmitted from the first conductive pattern to be lower than a preset strength associated with driving of the at least one camera.

According to an embodiment, the method of the electronic device may comprise monitoring the control signal by a preset period (e.g., the preset period 430 of FIG. 4).

According to an embodiment, the method of the electronic device may comprise receiving the control signal based on the preset period associated with exchanging of the control signal to communicate with the external electronic device based on all of a plurality of wireless communication protocols supported by the external electronic device which is a base station.

According to an embodiment, the method of the electronic device may comprise increasing the preset period to monitor the control signal based on receiving the control signal including another data different from data indicating the first time period.

According to an embodiment, the method of the electronic device may comprise adjusting a frequency corresponding to at least one of the first data signal or the second data signal based on the RF circuitry when transmitting the at least one of the first data signal or the second data signal.

According to an embodiment, the method of the electronic device may comprise performing an impedance matching of the first conductive pattern, based on capacitors to perform the impedance matching of the first conductive pattern, by controlling switches included in the RF circuitry based on an antenna code stored in memory (e.g., the memory 130 of FIGS. 1 and/or 2).

According to an embodiment, the method of the electronic device may comprise transmitting a third data signal included in the first data signal, to the external electronic device based on a first radio access technology (RAT). According to an embodiment, the method of the electronic device comprise transmitting a fourth data signal included in the first data signal, to the external electronic device based on a second RAT different from the first RAT.

According to an embodiment, the method of the electronic device may comprise transmitting information associated with whether to drive the at least one camera, to a communication processor from a processor.

According to an embodiment, the method of the electronic device may comprise adjusting, while transmitting the first data signal to the external electronic device, a strength of the first data signal transmitted from the first conductive pattern to be lower than the preset strength, by controlling all of the first conductive pattern and the second conductive pattern when receiving information that the at least one camera is driven from the processor.

According to an embodiment, the method of the electronic device may comprise transmitting the second data signal to the external electronic device by controlling the second conductive pattern when receiving information that the at least one camera is driven from the processor.

As described above, according to an embodiment, an electronic device (e.g., the electronic device 101 of FIGS. 1, 2, and/or 3) may comprise a housing, at least one camera (e.g., the camera 210 of FIG. 2) positioned on a surface of the housing, a first conductive pattern (e.g., the first conductive pattern 220 of FIG. 2) separated from the at least one camera by a first distance, a second conductive pattern (e.g., the second conductive pattern 230 of FIG. 2) separated from the at least one camera by a second distance longer than the first distance, a communication processor (e.g., the communication processor 240 of FIG. 2) to control the first conductive pattern and the second conductive pattern. The communication processor may be configured to control each of the first conductive pattern and the second conductive pattern based on different frequencies in a first state of transmitting a data signal using all of the first conductive pattern and the second conductive pattern. The communication processor may be configured to adjust a strength of the data signal transmitted through the first conductive pattern controlled based on a first frequency to be lower than or equal to a preset strength in the first state in which the first frequency of the first conductive pattern is higher than a second frequency of the second conductive pattern. The communication processor may be configured to transmit a data signal having a strength higher than the preset strength by controlling the second conductive pattern among the first conductive pattern and the second conductive pattern based on a third frequency higher than the first frequency in a second state different from the first state.

According to an embodiment, the electronic device may comprise a memory (e.g., the memory 130 of FIGS. 1, and/or 2) and a radio frequency (e.g., the RF circuitry 250 of FIG. 2). The RF circuitry is connected to the first conductive pattern through switches, and comprises capacitors to perform impedance matching of the first conductive pattern. The communication processor may be configured to perform the impedance matching of the first conductive pattern based on the capacitors by controlling the switches based on an antenna code stored in the memory.

According to an embodiment, the communication processor may be configured to receive a control signal for transmitting the data signal from an external electronic device. The communication processor may be configured to monitor the control signal at a preset period.

According to an embodiment, the communication processor may be configured to transmit the data signal to at least one of the first frequency, the second frequency, and the third frequency through at least one of the first conductive pattern and the second conductive pattern based on the control signal.

The electronic device according to One or more embodiments may be one of various types of electronic devices. The electronic devices may include, for example, a portable communication device (e.g., a smartphone), a computer device, a portable multimedia device, a portable medical device, a camera, a wearable device, or a home appliance. According to an embodiment of the disclosure, the electronic devices are not limited to those described above.

One or more embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. A singular form of a noun corresponding to an item may include one or more of the things unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). If an element (e.g., a first element) is referred to, with or without the term “operatively” or “communicatively”, as “coupled with,” or “connected with” another element (e.g., a second element), it means that the element may be coupled with the other element directly (e.g., wiredly), wirelessly, or via a third element.

As used in connection with one or more embodiments of the disclosure, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

One or more embodiments of the disclosure may be implemented as software (e.g., the program 140) including one or more instructions that are stored in a storage medium (e.g., internal memory 136 or external memory 138) that is readable by a machine (e.g., the electronic device 101). For example, a processor (e.g., the processor 120) of the machine (e.g., the electronic device 101) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between a case in which data is semi-permanently stored in the storage medium and a case in which the data is temporarily stored in the storage medium.

According to an embodiment, a method according to one or more embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to one or more embodiments, each component (e.g., a module or a program) of the above-described components may include a single entity or multiple entities, and some of the multiple entities may be separately disposed in different components. According to one or more embodiments, one or more of the above-described components may be omitted, or one or more other components may be added. Alternatively or additionally, a plurality of components (e.g., modules or programs) may be integrated into a single component.

In such a case, according to One or more embodiments, the integrated component may still perform one or more functions of each of the plurality of components in the same or similar manner as they are performed by a corresponding one of the plurality of components before the integration. According to one or more embodiments, operations performed by the module, the program, or another component may be carried out sequentially, in parallel, repeatedly, or heuristically, or one or more of the operations may be executed in a different order or omitted, or one or more other operations may be added.

No claim element is to be construed under the provisions of 35 U.S.C. § 112, sixth paragraph, unless the element is expressly recited using the phrase “means for” or “means.”

What is claimed is:

1. An electronic device comprising:
at least one camera;
a first conductive pattern separated from the at least one camera by a first distance;
a second conductive pattern separated from the at least one camera by a second distance, the second distance being longer than the first distance; and
a communication processor configured to transmit a data signal to an external electronic device and configured to receive a control signal from the external electronic device, through the first conductive pattern and the second conductive pattern,
wherein the communication processor is further configured to:
transmit a first data signal to the external electronic device by controlling the first conductive pattern and the second conductive pattern in a first time period indicated by the control signal transmitted from the external electronic device;
transmit a second data signal to the external electronic device by controlling the second conductive pattern in a second time period different from the first time period; and
adjust, when the at least one camera is operated in the first time period, a strength of the first data signal to be lower than a preset strength associated with an operation of the at least one camera.

2. The electronic device of claim 1, wherein the communication processor is further configured to monitor the control signal by a preset period.

3. The electronic device of claim 2, wherein the communication processor is further configured to receive the control signal based on the preset period associated with exchanging of the control signal to communicate with the external electronic device based on a plurality of wireless communication protocols supported by the external electronic device.

4. The electronic device of claim 2, wherein the communication processor is further configured to increase the preset period to monitor the control signal based on receiving the control signal including another data that is different from data indicating the first time period.

5. The electronic device of claim 1, further comprising radio frequency (RF) circuitry,
wherein the communication processor is further configured to adjust a frequency corresponding to at least one of the first data signal or the second data signal based on the RF circuitry when transmitting the at least one of the first data signal or the second data signal.

6. The electronic device of claim 1, further comprising memory,
wherein the RF circuitry is connected to the first conductive pattern through switches and the RF circuitry comprises capacitors to perform impedance matching of the first conductive pattern, and
wherein the communication processor is further configured to perform the impedance matching of the first conductive pattern based on the capacitors by controlling the switches based on an antenna code in the memory.

7. The electronic device of claim 1, wherein the first data signal comprises a third data signal and a fourth data signal, and
wherein the communication processor is further configured to:
transmit the third data signal in the first data signal, to the external electronic device, based on a first radio access technology (RAT), and
transmit the fourth data signal in the first data signal, to the external electronic device, based on a second RAT.

8. The electronic device of claim 7, wherein the communication processor is further configured to:
transmit the third data signal through a second frequency range within a first frequency range,
transmit the fourth data signal through a third frequency range that is higher than the second frequency range within the first frequency range.

9. The electronic device of claim 1, further comprising a processor configured to transmit, to the communication processor, information about the operation of the at least one camera.

10. The electronic device of claim 9, wherein the communication processor is further configured to adjust, when transmitting the first data signal to the external electronic device, a strength of the first data signal to be lower than the preset strength, by controlling the first conductive pattern and the second conductive pattern when receiving, from the processor, information about the operation of the at least one camera.

11. The electronic device of claim 10, wherein the communication processor is further configured to transmit the second data signal, to the external electronic device, by controlling the second conductive pattern when receiving, from the processor, the information about the operation of the at least one camera.

12. A method of an electronic device, the method comprising:
transmitting, in a first time period indicated by a control signal transmitted from an external electronic device, a first data signal to the external electronic device by controlling a first conductive pattern separated from at least one camera by a first distance, and a second conductive pattern separated from the at least one camera by a second distance that is longer than the first distance;
transmitting, in a second time period different from the first time period, a second data signal to the external electronic device by controlling the second conductive pattern;
transmitting, in the second time period, the second data signal to the external electronic device by controlling the second conductive pattern; and
adjusting, in the first time period, a strength of the first data signal to be lower than a preset strength associated with an operation of the at least one camera.

13. The method of claim 12, further comprising monitoring the control signal by a preset period.

14. The method of claim 13, further comprising receiving the control signal based on the preset period associated with exchanging of the control signal to communicate with the external electronic device based on a plurality of wireless communication protocols supported by the external electronic device.

15. The method of claim 13, further comprising increasing the preset period to monitor the control signal based on receiving the control signal including another data different from data indicating the first time period.

16. The method of claim 12, further comprising adjusting a frequency corresponding to at least one of the first data signal or the second data signal based on a radio frequency (RF) circuitry of the electronic device when at least one of the first data signal or the second data signal is transmitted.

17. The method of claim 12, further comprising performing an impedance matching of the first conductive pattern based on capacitors to perform impedance matching of the first conductive pattern by controlling switches in the RF circuitry based on an antenna code in a memory.

18. The method of claim 12, further comprising:
transmitting a third data signal in the first data signal to the external electronic device based on a first radio access technology (RAT); and
transmitting a fourth data signal in the first data signal to the external electronic device based on a second RAT different from the first RAT.

19. The method of claim 12, further comprising transmitting information about the operation of the at least one camera, to a communication processor from a processor.

20. The method of claim 12, further comprising adjusting a strength of the first data signal to be lower than the preset strength by controlling the first conductive pattern and the second conductive pattern when information about the operation of the at least one camera is received from a processor.
